(19) United States
(12) Patent Application Publication
(10) Pub. No.: US 2009/0296799 A1
(43) Pub. Date: Dec. 3, 2009

(54) Channel identification, emulation, and frame synchronization for digital television signals

(76) Inventors: Raul Alejandro Casas, Doylestown, PA (US); Stephen Leonard Biracree, Rochester, NY (US); Slobodan Simovich, San Francisco, CA (US); Thomas Joseph Endres, Seattle, WA (US)

Correspondence Address: OLYMPIC PATENT WORKS PLLC, P.O. BOX 4277, SEATTLE, WA, 98104, US

(21) Appl. No.: 12/381,375

(22) Filed: Mar. 10, 2009

Related U.S. Application Data
(60) Provisional application No. 61/069,211, filed on Mar. 12, 2008.

(51) Int. Cl. H04N 7/24; H03K 5/159

(52) U.S. Cl. 375/231; 375/E07.002

(57) ABSTRACT

The present invention is related to channel identification, equalizer initialization, and framing synchronization of GB 20600-2006 digital television signals. In one embodiment, the present invention provides, in a communications receiver having an equalizer that processes GB 20600-2006 digital television signals that include payload data, a method that initializes the equalizer coefficients for processing the payload data comprising: identifying a channel estimate based on correlation techniques; producing known, mock received data and filtering the mock, received data through the channel estimate to produce mock filtered data; adjusting the equalizer coefficients with the mock received data or the mock filtered data to obtain an initial equalizer setting; and processing the payload data with the initial equalizer setting.

### CROSS REFERENCE TO RELATED APPLICATION

This application claims the benefit of U.S. Provisional Application No. 61/069,211, filed Mar. 12, 2008.

### FIELD OF INVENTION

The present invention is related to equalization and frame synchronization of signals for digital television signals.

### BACKGROUND OF INVENTION

Equalization in a digital receiver is a process whereby multipath, noise, and other interferences incurred in the digital broadcast are removed from the received signal, and attempts are made to restore the original digital transmission. Since the characteristics of the broadcast channel are rarely known a priori to the receiver, and can change dynamically, equalizers are usually implemented using adaptive filters.

Most state-of-the-art digital receivers use some type of decision feedback equalizer (DFE), because it provides superior inter-symbol interference (ISI) cancellation with less noise gain than a linear equalizer structure. Austin first proposed a DFE, in a report entitled “Decision feedback equalization for digital communication over dispersive channel's,” MIT Lincoln Labs Technical Report No. 437, Lexington, Mass., August 1967. A DFE acts to additively cancel ISI by subtracting filtered symbol estimates from the received waveform.

The GB 20600-2006 Chinese National Standard, entitled “Framing structure, channel coding and modulation for digital television terrestrial broadcasting system” published Aug. 18, 2006, executed Aug. 1, 2007 describes the physical layer characteristics of the digital television transmission adopted in China, which is already deployed in some regions. Approximately one third of the televisions sold in the world are sold in China.

The present invention uses novel techniques to identify the transmission channel, synchronize to the framing structure of GB 20600-2006 signals, and initialize the equalizer adaptive filters for processing of payload data.

### SUMMARY OF INVENTION

The present invention is related to channel identification, equalizer initialization, and framing synchronization of digital television signals.

### BRIEF DESCRIPTION OF DRAWINGS

Other aspects, features, and advantages of the present invention will become more fully apparent from the following detailed description, the appended claims, and the accompanying drawings and tables in which:

FIG. 1 shows a typical prior art digital television broadcast communication

system;

FIG. 2 shows a typical prior art digital receiver system;

FIG. 3 shows a prior art decision feedback equalizer;

FIG. 4 shows a decision feedback equalizer in accordance with the present invention;

FIG. 5 shows a top level view of channel identification circuitry in accordance with the present invention;

FIG. 6 shows channel estimation averaging circuitry in accordance with the present invention;

FIG. 7 shows a frame synchronization state machine in accordance with the present invention;

FIG. 8 shows pre-stage correlation calculations in frame synchronization state-machine in accordance with the present invention;

FIG. 9 shows frame synchronization state-0 in accordance with the present invention;

FIG. 10 shows frame synchronization state-1 in accordance with the present invention;

FIG. 11 shows frame synchronization state-2 in accordance with the present invention;

FIG. 12 shows frame phase determination in frame synchronization state-2 in accordance with the present invention;

FIG. 13 shows frame synchronization state-3 in accordance with the present invention;

FIG. 14 shows a loss-of-lock test in accordance with fee present invention; and

FIG. 15 shows channel emulation (CEMU) circuitry in accordance with the present invention.

### DETAILED DESCRIPTION

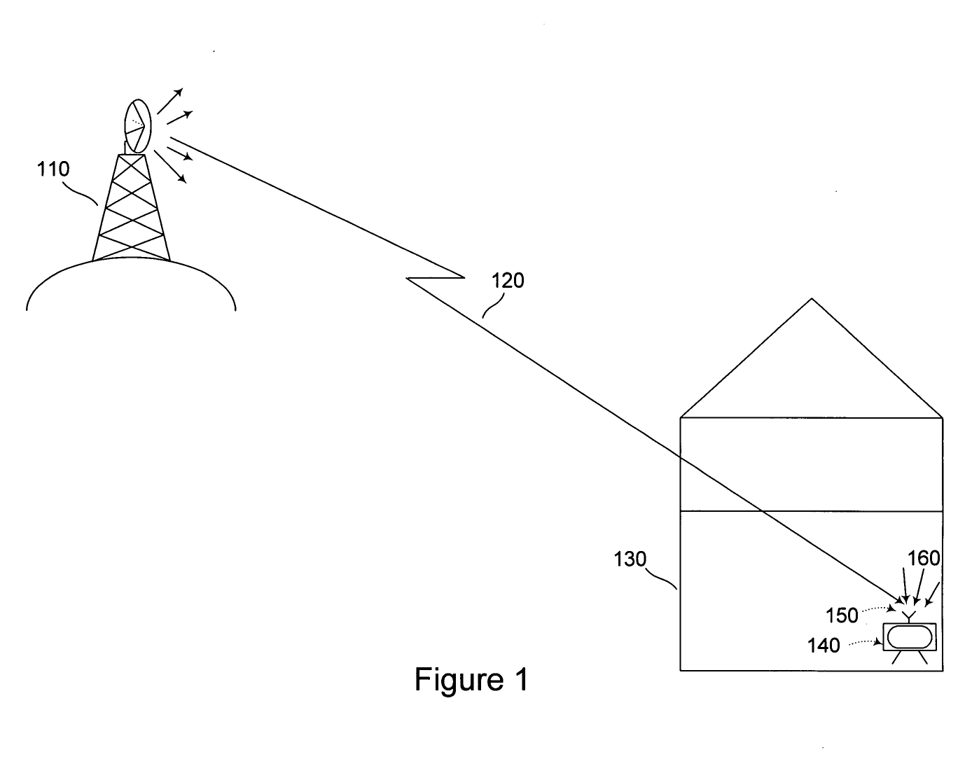

FIG. 1 depicts a typical prior art digital television broadcast communication system, used as an exemplary communication system for which the present invention is applicable. Transmitter station 110 broadcasts Digital Television (DTV) signal 120, which radiates through house 130 to antenna 150. The induced penetration loss of the RF carrier's signal power through house 130 can be significant, easily 20 dB. Antenna 150 is usually in close proximity to television 140, or can be remotely connected to television 140. Antenna 150 also receives multipath signals, collectively 160, which can be caused by reflections from other buildings, or items interior to house 130, such as walls, furniture, persons, etc. Furthermore, in most viewing environments, the television 140 is located in a communal part of house 130, so that reflections from moving persons, etc. induce time varying multipath signals 160. Any reflections from moving cars or airplanes cause further time variations in multipath signals 160.

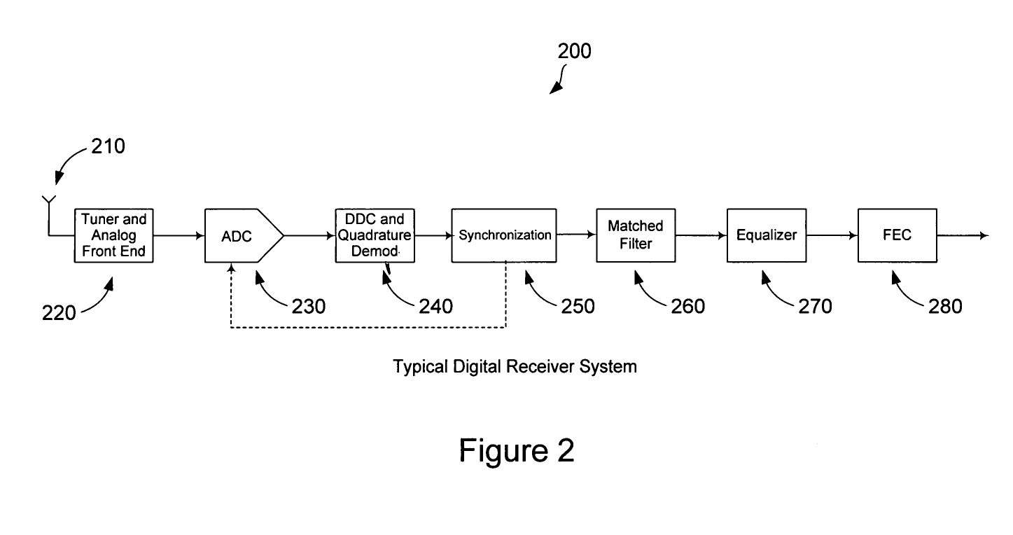

FIG. 2 shows a typical prior art digital receiver system 200. Antenna 210 receives DTV broadcast signal 120, and is coupled to Tuner and Analog Front End module 220. Tuner and Analog Front End module 220 tunes to the proper broadcast channel, performs level setting, synchronization, and filtering, and couples the signal to analog-to-digital converter (ADC) 230. ADC 230 digitizes the analog signal, typically 10-12 bits for DTV, and supplies the sample stream to direct digital down-converter (DDC) and quadrature demodulation module 240, DDC and quadrature demodulation module 240 performs direct digital down-conversion and in-phase/quadrature-phase split into complex near-baseband. In addition, other filtering may be used, for example, rejection of adjacent broadcasts, and other level setting/gain adjustment may be done in DDC and quadrature demodulation module 240. The near-baseband signal from DDC and quadrature demodulation module 240 is coupled to synchronization module 250. Synchronization module 250 aligns the sample rate and phase of the received samples to the transmitted data samples, by known methods, typically either interpolating the data or adjusting the sample clock of ADC 230, shown in phantom. Furthermore, carrier phase and frequency recovery may be done using the pilot tone(s) that, are embedded into the DTV data spectrum, using known methods. Timed data from synchronization module 250 is supplied to matched filter 260, which usually performs square-root raised cosine filtering that is matched to the pulse shape filter applied at the transmitter 110. The output of matched filter 260 is supplied to Equalizer 270, which performs adaptive equalization to mitigate inter-symbol interference incurred in the broadcast channel. Furthermore, equalizer 270 may include a fine earner recovery loop, translating the data to precise baseband. Equalizer 270 provides an equalized signal to FEC 280, which performs forward error correction to minimize the received bit error rate and provides fee recovered digital video signal, usually as MPEG packets, which can be decoded and viewed on a television. The present invention pertains to the equalizer 270 in the digital receiver.

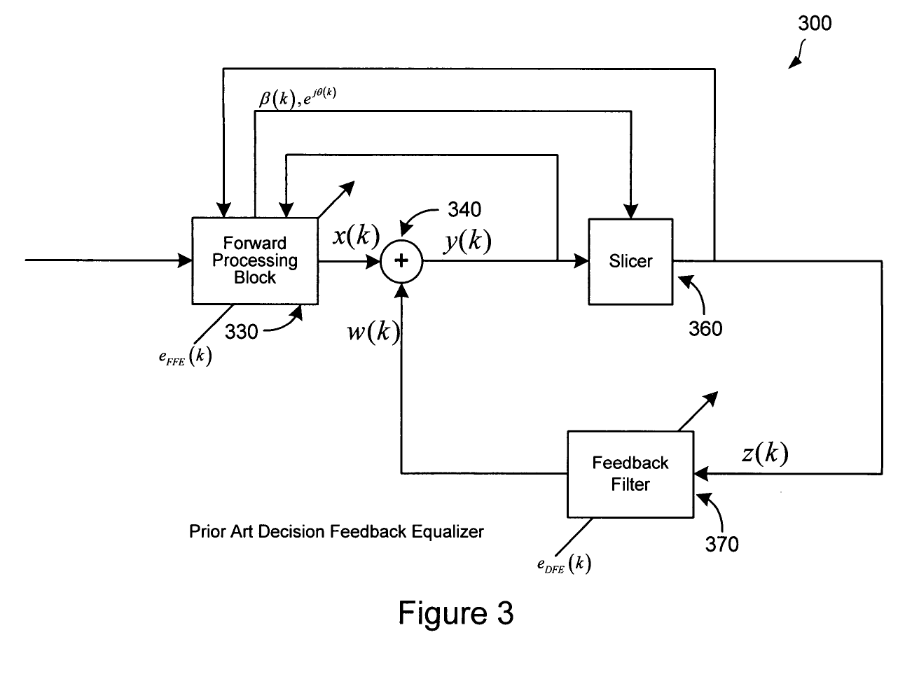

FIG. 3 depicts a block diagram of a prior art equalizer and encapsulates the equalizer architectures described in “Feasibility of reliable 8-VSB reception” by C. H. Strolle et al, Proceedings of the NAB Broadcast Engineering Conference,” Las Vegas, Nev., pp. 483-488, Apr. 8-13, 2000, among other prior art equalizer architectures. The equalizer in FIG. 3 is suitable for Vestigial Sideband (VSB) signals, for example, in accordance with the ATSC DTV broadcast standard. The equalizer in FIG. 3 is also suitable for QAM signals, encapsulating the equalizer architecture described in “Carrier independent blind initialization of a DFE,” by T. J. Endres et al., in Proceedings of the IEEE Workshop on Signal Processing Advances in Wireless Communications, Annapolis, Md., May 1999. Therefore the equalizer in FIG. 3 is suitable for GB 20600-2006 signals, as described in GB 20600-2006 Chinese National Standard, entitled “Framing structure, channel coding and modulation for digital television terrestrial broadcasting system” published Aug. 18, 2006, executed Aug. 1, 2007.

Forward processing block 330 encompasses multiple prior art signal processing functions, and may include circuitry for adaptive forward filtering, carrier recovery, error term generation, et al., for example. See “Phase detector in a carrier recovery network for a vestigial sideband signal,” U.S. Pat. No. 5,706,057 issued Jan. 6, 1998, by C. H. Strolle et al., for carrier recovery techniques suitable to VSB signals. For QAM signals, decision-directed carrier estimation techniques are described in Chapter 16 of Digital Communication—Second Edition, Lee and Messerschmitt, Kluwer Academic Publishers, Boston, Mass., 1997. See Theory and Design of Adaptive Filters, Hew York, John Wiley and Sons, 1987, by Treichler et al for a description of adaptive filters, including forward adaptive filtering and error term generation.

Forward processing block 330 receives input samples from front end signal processing blocks of the digital receiver, for example from matched filter 260, as shown in FIG. 2, Forward processing block 330 also receives soft decision sample y(k) input to sheer 360, and also receives output of slicer 360. Forward processing block 330 further may provide output to slicer 360, for example to provide sine and cosine terms to slicer 360 if slicer 360 is to form passband samples, as described in “Carrier independent blind initialization of a DFE,” by T. J. Endres et al., in Proceedings of the IEEE Workshop on Signal Processing Advances in Wireless Communications, Annapolis, Md., May 1999. Gain correction terms may also be supplied to slicer 360 from forward processing block 330; gain and phase correction terms are represented by β(k) and θ(k) in β(k),e^{jθ(k)} in FIG. 3. Forward processing block 330 also receives an error term e_{FFE}(k), which can be used to adjust adaptive filter coefficients contained in forward processing block 330. Note that error term e_{FFE}(k) may be generated in forward processing block 330, in slicer 360, or elsewhere in the receiver.

Adder 340 combines x(k) with feedback filter 370 output w(k) to provide sample y(k), referred to as the equalizer output, or soft-decision sample; combining can either be done with addition or subtraction, depending upon other polarity choices made. Soft decision sample y(k) is provided to slicer 360. Slicer 360 produces a, symbol estimate (also referred to as a hard decision sample). Slicer 360 can be a nearest-element decision device, selecting the source symbol with minimum Euclidean distance to the soft decision sample, or can take advantage of the channel coding. For example, a partial trellis decoder is used as sheer 360 in “A method of estimating trellis encoded symbols utilizing simplified trellis decoding,” U.S. Pat. No. 6,178,209, issued Jan. 23, 2001, by S. N. Hulyalkar et al. Slicer 360 may also include a soft symbol estimator, which processes the soft decision sample through, a performance-enhancing non-linear function, like that described in J. Salz, “Optimal mean square decision feedback equalization,” Bell Systems Technical Journal, pp. 1341-1373, October 1973, Slicer 360 may also receive an input signal from forward processing block 330, for example, including sine and cosine terms which may be used for rotation and de-rotation in accordance with previously cited prior art techniques.

The output from slicer 360 is used to form regressor sample z(k) for feedback filter 370. Feedback filter 370 receives regressor samples z(k) and produces output sample w(k) to adder 340. Feedback filter 370 is usually implemented with adaptive coefficients, and is therefore provided error term e_{DFE}(k), which may be generated in forward processing block 330, in sheer 360, or elsewhere in the receiver.

The adaptive filters contained in forward processing block 330 and feedback filter 370 may be comprised of real- or complex-valued coefficients, may process real- or complex-valued data, and may adjust coefficients or blocks of coefficients using real- or complex-valued error.

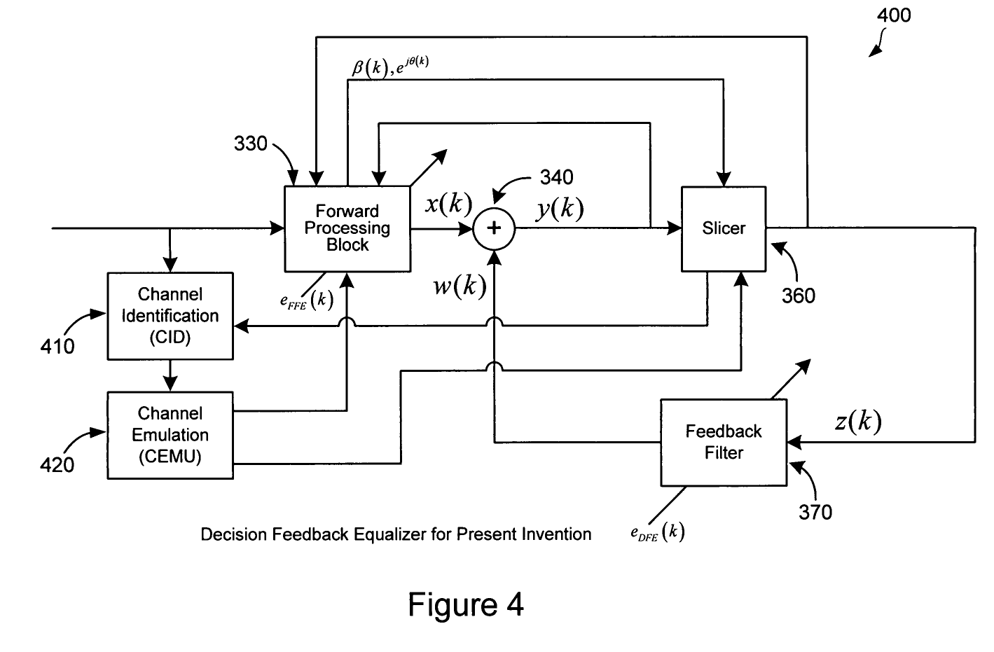

FIG. 4 shows a decision feedback equalizer 400 in accordance with the present invention. Channel Identification (CID) block 410 contains novel correlation and frame synchronization techniques and derives a channel estimate. Similar or identical frame synchronisation techniques can be applied also in slicer 360, but are described here in conjunction with the channel identification block 410. To obtain an equalizer setting that is appropriate for adaptation to payload data, the channel estimate found in channel identification block 410 is supplied to channel emulation block 420. Channel emulation block 420 creates a known data sequence, for example using a PN random number generator, and filters this known data sequence through the channel estimate provided by channel identification block 420, thus creating an input/output data record that can be used to train the adaptive filters in forward processing block 330 and feedback filter 370. Both the input and output data records are supplied from the channel emulation 420 block to forward processing block 330 to form error terms e_{FFE}(k) and e_{DFE}(k) and gain and phase correction terms β(k),e^{jθ(k)}. The output data record is also supplied to slicer 360, and can be used to form a feedback sample z(k), input to the feedback filter 370, for example. Operation of channel identification 410 and channel emulation 420 blocks to run the equalizer 400 in this manner are next described.

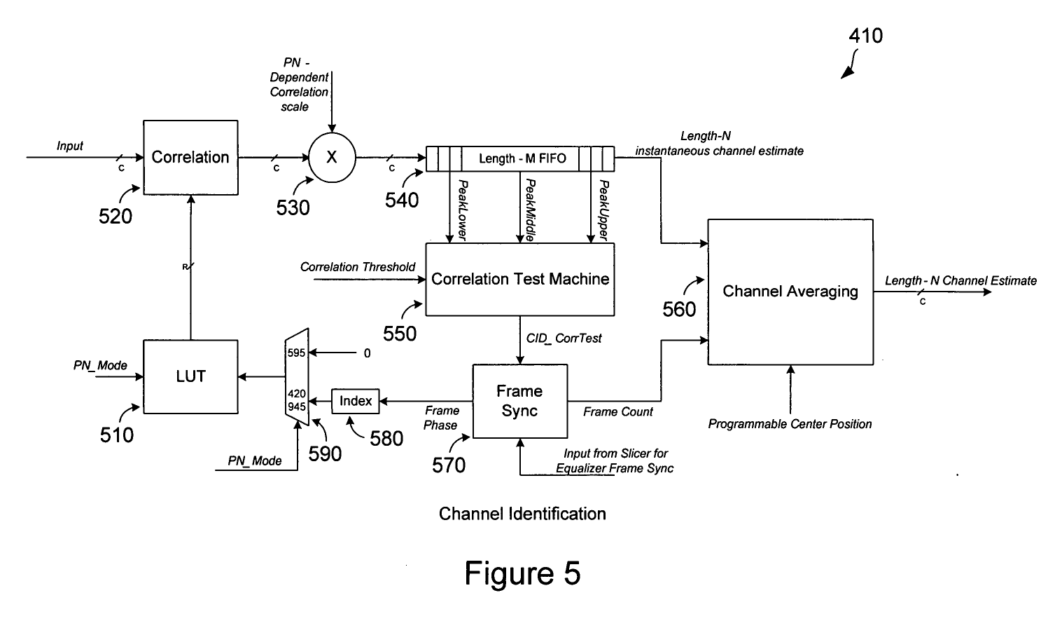

FIG. 5 shows a top level view of channel identification block 410 in accordance with the present invention. The channel identification block 410 uses correlation techniques against the PN data in the Frame Header portion of the GB20600-2006 Signal Frame with the output matched filter 260 in correlation block 520. Correlation block 520 calculates a complex-valued correlation sample u(n), for example of the form

$$u ( n ) = {\sum }_{k = 0}^{T - 1} p ( k ) \cdot {r}_{1} ( n + k ) + j \cdot {\sum }_{k = 0}^{T - 1} p ( k ) \cdot {r}_{Q} ( n + k )$$

where p(k) is the one-bit data from LUT 510, and r(n)=r₁(n)+jr_{Q}(n) is the complex-valued output of matched filter 260. LUT 510 stores or generates the PN data in the Frame Header portion of the GB20600-2006 Signal Frame, which is different for each PN mode. The length of the correlation depends on the PN mode, and is T=255, 595, 511 for header modes PN420, PN595, and FN945, respectively.

The complex-valued correlation sample u(n) from correlation block 520 is scaled in multiplier 530 by a PN-dependent correlation scale, and stored in a length-M FIFO 540. The length of the FIFO 540 may be M=1200, for example. The FIFO 540 contents at position Δ₁+0 are assigned to PeakLower; FIFO 540 contents at position Δ₁+T−1 to PeakMiddle, and FIFO 540 contents at position Δ₁+2T−1 to PeakUpper and passed to correlation test machine 550. Here, again T=255, 595, 511 for header modes PN420, PN595, and PN945, respectively, and scalar Δ₁ is a programmable offset to read the FIFO 540 contents.

Correlation test machine 550 receives complex-valued PeakLower, PeakMiddle, and PeakUpper from the FIFO 540 and compares the absolute value of real and imaginary parts of PeakMiddle to a programmable correlation threshold. When the sum of absolute value of real and absolute value of imaginary components is greater than the correlation threshold, the magnitude of PeakMiddle is compared to both PeakLower and PeakUpper. When the magnitude of PeakMiddle is greater than both the magnitudes of PeakLower and PeakUpper, then the correlation test is said to pass and CID_CorrTest is set to 1; otherwise, the correlation test is said to fail and CID_CorrTest is set to 0. When the correlation test succeeds, the Frame Sync 570 is enabled, When the correlation test fails, FIFO 540 continues to be loaded. Note that lower and upper peaks are checked to prevent a false lock, possible because of the pre-amble and post-amble in the GB20600-2006 frame header.

When Frame Sync 570 declares lock, a valid instantaneous channel estimate is produced from FIFO 540 contents Δ₂+0 . . . Δ₂+N (N=255, for example, and scalar Δ₂ is a programmable offset to read the FIFO 540 contents). The channel estimate is provided to the channel averaging circuit block 560. Also when Frame Sync 570 declares lock, the Frame Phase is determined. Note that for header modes PN420 and PN945, the phase of the PN data in the Frame Header cycles from signal frame to signal frame within a super frame. Hence, Index block 580 is used to calculate the index of the sequence in the Frame Header based on the frame phase determined from Frame Sync 570, so multiplexor 590 selects the index provided by Index block 580 for PN420 and PN945, but selects a zero value for PN595, and is used to select the address of LUT 510.

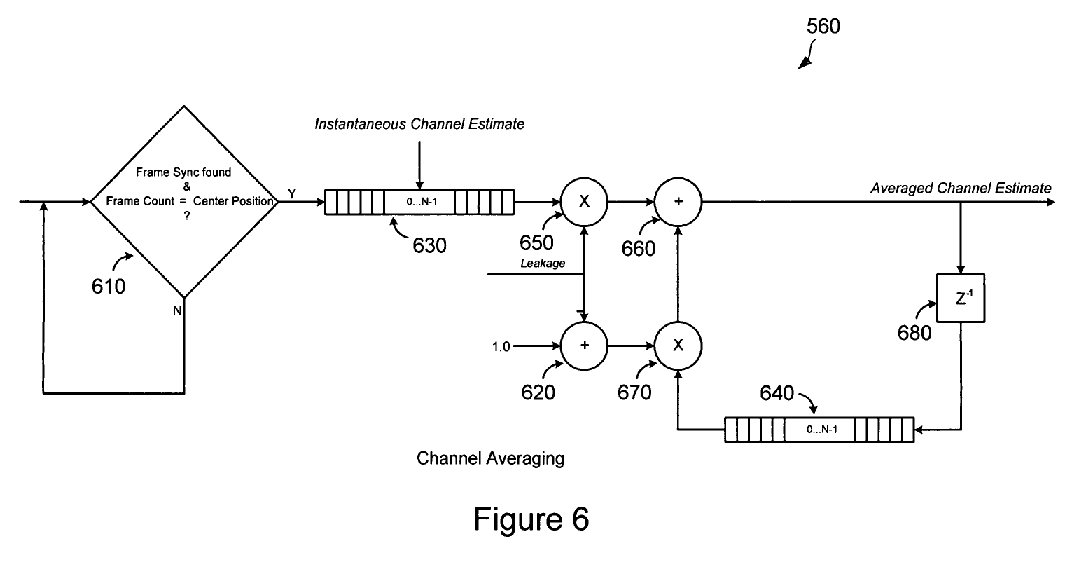

FIG. 6 shows channel averaging block 560 in accordance with the present invention. In channel averaging block 560, the instantaneous channel estimate is averaged in leaky integrator circuitry applied to the vector of channel estimates. Decision block 610 enables the leaky integrator circuitry when Frame Sync 570 declares lock and the Frame Count in Frame Sync 570 corresponds to the programmable center position. When enabled by decision block 610, instantaneous channel estimate from FIFO 540 is placed in buffer 630. Multiplier 650 applies a leakage term to all elements of buffer 630, and the result is added to the output of multiplier 670 in adder 660. Note that multipliers 670 and 650 represent scalars which operate on vectors, while adder 660 represents vector addition, done element-by-element. Adder 660 produces an averaged channel estimate, c(k)=c_{I}(k)+jc_{Q}(k),k=0.255, which is delayed in delay element 680 and stored in feedback buffer 640. Multiplier 670 applies the scalar value obtained by subtracting the leakage, term from one in adder 620 to the feedback buffer 640 contents, and the result is added to the scaled instantaneous channel estimate in adder 660, producing the averaged channel estimate.

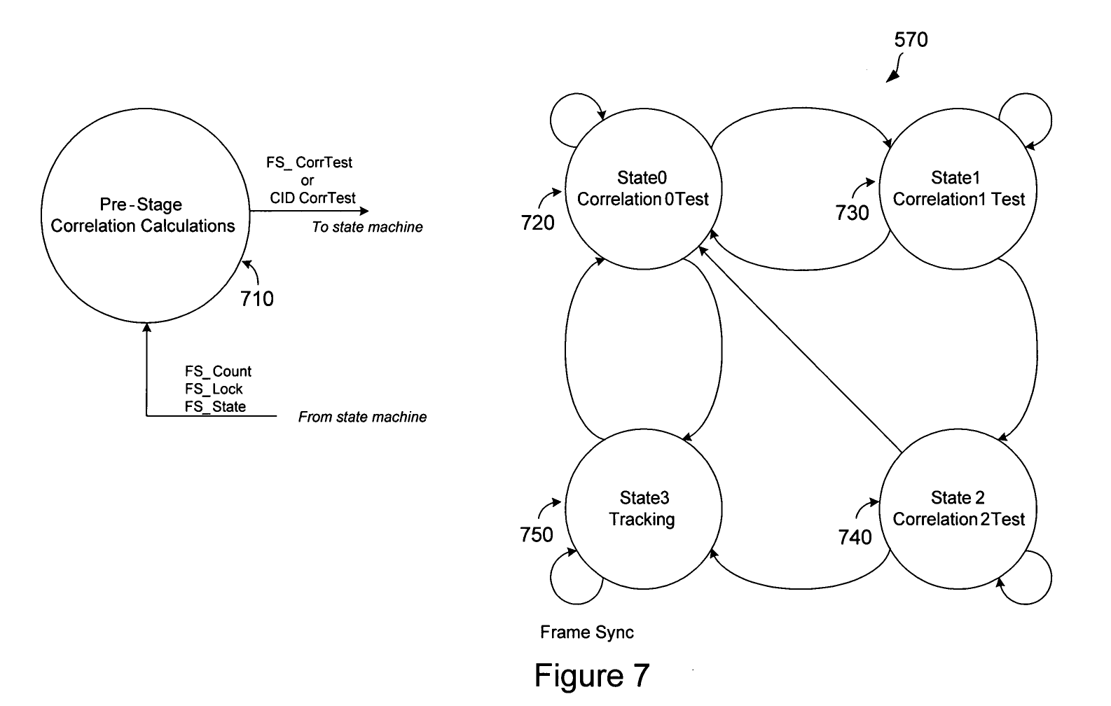

FIG. 7 shows Frame Sync 570 state machine in accordance with the present invention. The circuitry in frame sync 570 can be used in conjunction with the channel identification block 410, processing matched filter 260 outputs, or in the equalizer 400 processing equalizer outputs, y(k), for example. Pre-stage correlation calculations block 710 performs correlation against the PN data in the Frame Header of the GB20600-2006 signal, and provides signal FS_CorrTest to the state machine, which consists of states 0, 1, 2, and 3, shown in state blocks 720, 730, 740, and 750, respectively. State 0 (720) entitled “Correlation 0 Test” performs a first correlation test, and transitions to State 1 or stays at State 0. State 1 (730) entitled “Correlation 1 Test” performs a second correlation test, and transitions to State 2 or stays at State 1. State 2 (740) entitled “Correlation 2 Test” performs a third correlation test, and transitions to State 3, stays at State 2, or transitions back to State 0. State 3 (750) entitled “Tracking” stays in State 3 or transitions back to State 0.

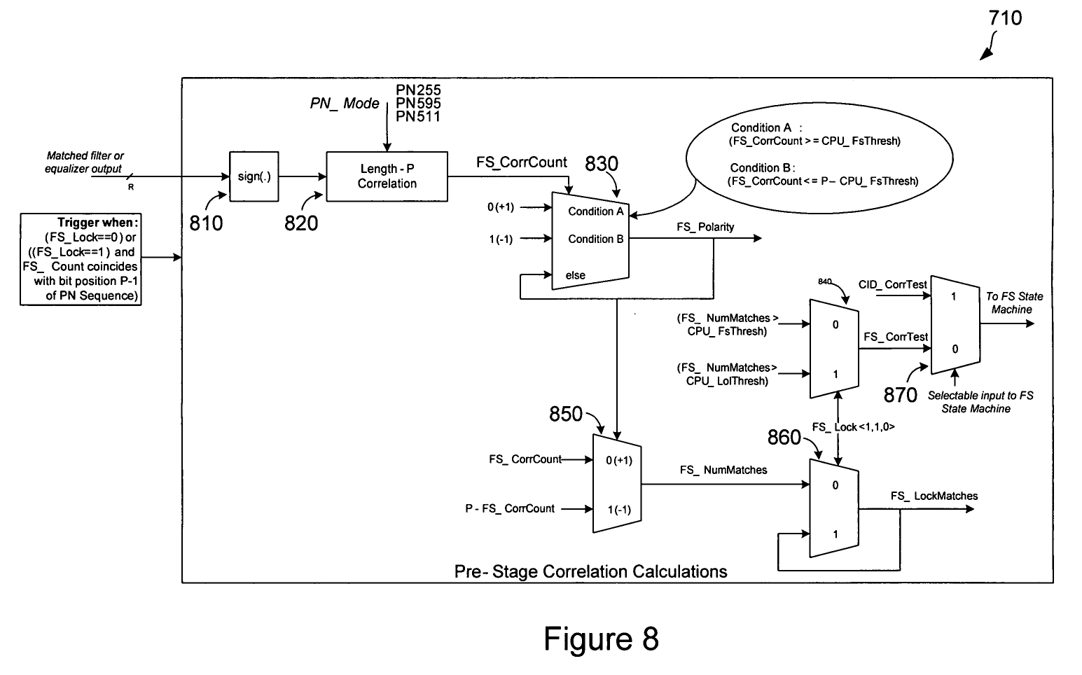

FIG. 8 shows pre-stage correlation calculations 710 in frame synchronization state-machine in accordance with the present invention. Framing is found based on correlation with the first P, (e.g., P=255) samples of PN data, which depends on the GB20600 header mode. For header mode 420, PN255 is used; for header mode 595, PN595 is used; and for header mode 945, PN511 is used. Pre-stage correlation calculations are enabled prior to frame lock, or after frame lock, when the FS_Count parameter coincides with bit position P-1 of PN sequence.

The sign bit from real part of the matched filter 260 or equalizer 400 output is extracted in sign extractor 810, and a one-bit by one-bit correlation against the PN data p(k) is done in length-P correlation 820, calculating the sum

$$v ( n ) = {\sum }_{k = 0}^{P - 1} p ( k ) ⊗ r ( n - k )$$

where the binary operator [symbol] is defined according to

$$a ⊗ b = {\{}_{0 , else}^{1 ⇔ ( a = b )}$$

Note that [symbol] denotes “if and only if”. Hence, FS_CorrCount=v(n) counts the number of matches among P possible where p(k)=0 and r(n−k)=0, or where p(k)=1 and r(n−k)=1. The sense of r(n) used in the correlation is defined as 0 if the sign of equalizer output is +1, and 1 if the sign of equalizer output is −1.

The signal FS_Polarity, a polarity, is derived in multiplexor 830 by comparing FS_CorrCount to programmable threshold CPU_FsThresh.

If FS_CorrCount>=CPU_FsThresh, then polarity is assigned a positive sense, +1;

If FS_CorrCount<=P−CPU_FsThresh, then polarity is assigned a negative sense, −1

The FS_Polarity from multiplexor 830 is used in multiplexor 850 to determine the parameter FS_NumMatches according to

If FS_Polarity is positive, then FS_NumMatches is assigned the value of FS_CorrCount;

If FS_Polarity is negative, then FS_NumMatches is assigned the value of P minus FS_CorrCount;

Multiplexor 860 assigns the current value of FS_NumMatches to FS_LockMatches until FS_Lock is enabled, at which point it freezes the value of FS_LockMatches.

Multiplexor 840 derives the binary FS_CorrTest parameter, which returns a binary decision based on FS_NumMatches>CPU_FsThresh before frame lock, and FS_NumMatches>CPU_LolThresh after frame lock. Both the parameters CPU_FsThresh and CPU_LolThresh are programmable thresholds. Binary parameter FS_CorrCount is coupled to an input of multiplexor 870.

Multiplexor 870 selects the input signal to the frame sync state machine, consisting of states 0, 1, 2, and 3, shown in state blocks 720, 730, 740, and 750, respectively in FIG. 7, as either the FS_CorrTest derived in multiplexor 840 in FIG. 8, or the CID_CorrTest derived in correlation test machine 550 in FIG. 5. The selection can be based on a higher-level control algorithm, for example, based on the quality of the channel estimate. For brevity, the following description of the frame sync state machine, consisting of states 0, 1, 2, and 3, shown in state blocks 720, 730, 740, and 750, respectively in FIG. 7, will use nomenclature solely for FS_CorrTest, but it is understood that CID_CorrTest could be used also.

FS_CorrTest is provided to the state machine, while FS_Polarity is used throughout equalizer signal processing when polarity ambiguity must be resolved. FS_LockMatches is a telemetry signal.

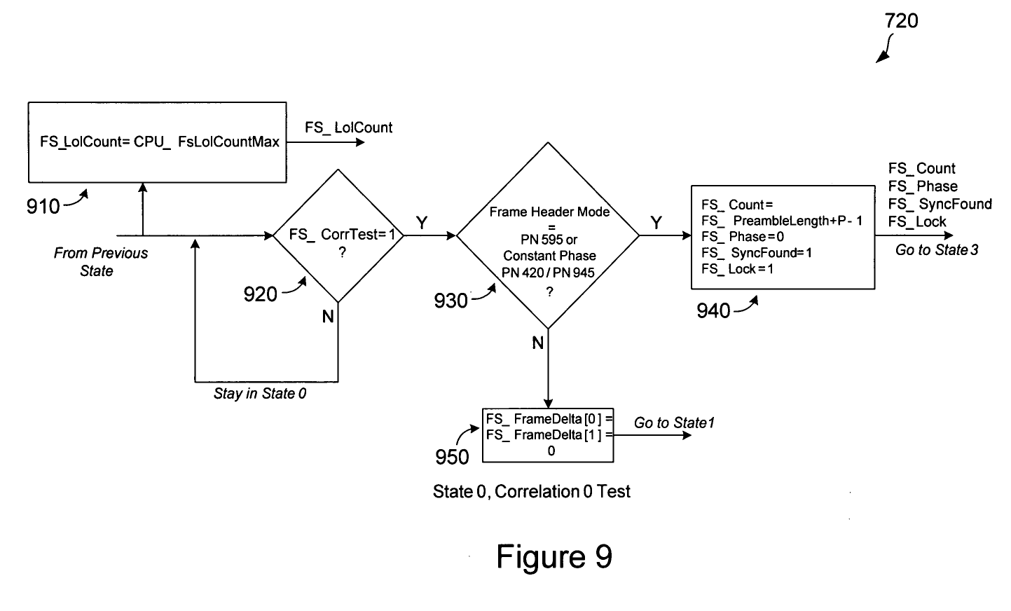

FIG. 9 shows Frame Synchronization state-0 (720) in accordance with the present invention. Assignment block 910 initializes FS_LolCount to programmable value CFU_FsLolCountMax, Decision block 920 waits to proceed until FS_CorrTest from pre-stage correlation calculations 710 (and output of multiplexor 840) is enabled. Decision block 930 separates processing to resolve rotating phase in the PN data, if needed. If the header mode is PN595, or “constant phase” option for PN420 or PN945, then assignment block 940 declares frame sync is found, and sets

### FS_Count=FS_PreambleLength+P−1

### FS_Phase=0

### FS_SyncFound=1

### FS_Lock=1

before proceeding directly to state 3 (750) Tracking. Note that FS_PreambleLength is the length of the pre-amble in the Frame Header, which is 82 for PN420, 0 for PN595 and 217 for PN945.

When, in decision block 930, PN420 or PN945 with rotating phase are selected, assignment block 950 is entered and FS_FrameDelta[0] and FS_FrameDelta[1] are initialized to zero before proceeding to state 1 (730) correlation test 1.

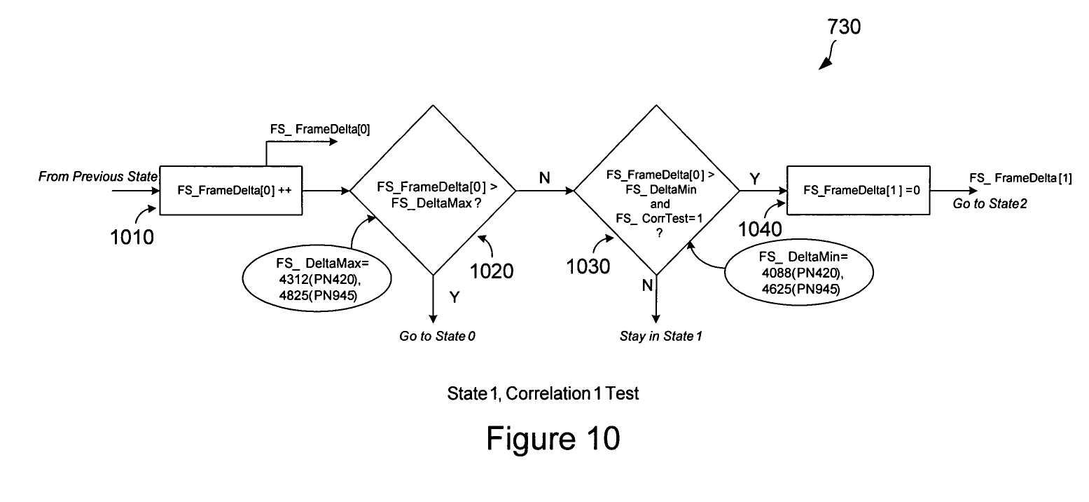

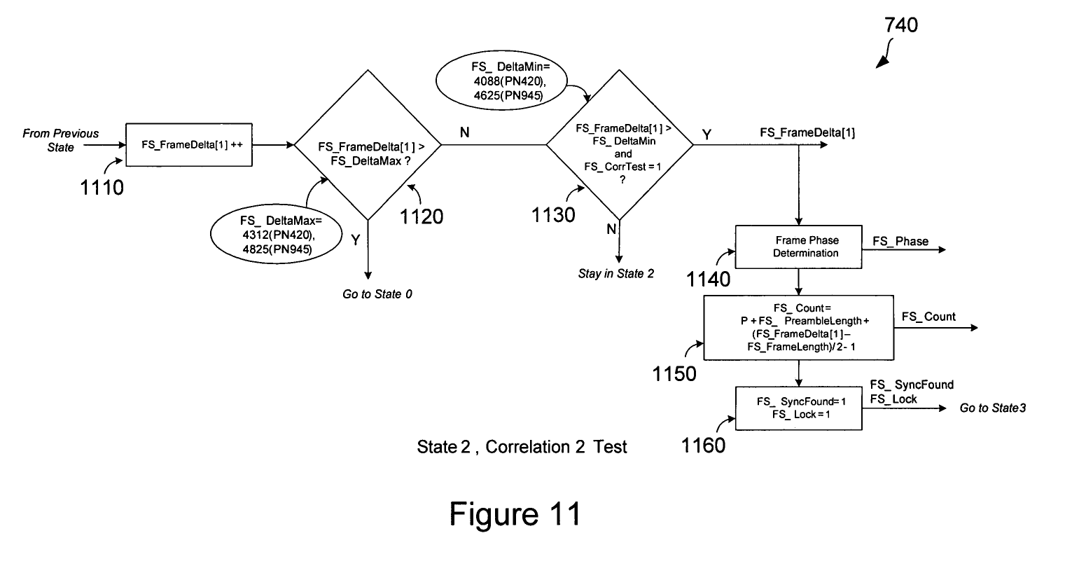

FIG. 10 shows frame synchronization state-1 (730) in accordance with the present invention. Frame phase will be determined by examining three consecutive correlations and counting the number of samples between them. Assignment block 1010 increments the value of FS_FrameDelta[0] and provides it as an output; it will be used in the frame phase determination 1140 in FIG. 11. Decision block 1020 checks to see that, the observation window has not passed, by comparing FS_FrameDelta[0] to programmable value FS_DeltaMax. The values for PN420 and PN945 GB20600-2006 signals are predetermined, in one embodiment of the present invention, to be 4312 and 4825, respectively. When, in decision block 1020, FS_FrameDelta[0]> FS_DeltaMax, then state 0 is re-entered. Otherwise, decision block 1030 is entered, in which is determined the value of FS_FrameDelta[0] corresponding to a successful correlation test from pre-stage correlation calculations 720. In decision block 1030, FS_FrameDelta[0] is compared to programmable value FS_DeltaMin, to enter the correct observation window. The values for PN420 and PN945 GB20600-2006 signals are predetermined, in one embodiment of the present invention, to be 4088 and 4625, respectively. Until FS_FrameDelta[0]>FS_DeltaMin and FS_CorrTest is valid from pre-stage correlation calculations 720, state 1 (730) is re-entered, otherwise, FS_FrameDelta[1] is initialized to zero in assignment block 1040, and state 2 (740) is entered.

FIG. 11 shows frame synchronization state-2 (740) in accordance with the present invention. Assignment block 1110 increments the value of FS_FrameDelta[1] and provides it as an output that is used in the frame phase determination 1140. Decision block 1120 checks to see that the observation window has not passed, by comparing FS_FramePelta[1] to programmable value FS_DeltaMax. The values for PN420 and PN945 GB20600-2006 signals are predetermined, in one embodiment of the present invention, to be 4312 and 4825, respectively. When, in decision block 11120, FS_FrameDelta[1]>FS_DeltaMax, state 0 is re-entered. Otherwise, decision block 1130 is entered, in which is determined the value of FS_FrameDelta[1] corresponding to a successful correlation test from pre-stage correlation calculations 720. In decision block 1130, FS_FrameDelta[1] is compared to programmable value FS_DeltaMin, to enter the correct observation window. The values for PN420 and PN945 GB20600-2006 signals are predetermined, in one embodiment of the present invention, to be 4088 and 4625, respectively. Until FS_FrameDelta[1]>FS_DeltaMin and FS_CorrTest is valid from pre-stage correlation calculations 720, state 2 (740) is re-entered, otherwise, FS_FrameDelta[1] is supplied to frame phase determination block 1140 (described subsequently). Frame phase determination block 1140 uses FS_FrameDelta[G] and FS_FrameDelta[1] to determine the Frame Phase, FS_Phase. Assignment block 1150 updates the FS_Count counter according to

FS_Count=P+FS_PreambleLength+(FS_FrameDelta[1,]FS_FrameLength)/2−1

where P is the correlation length, and FS_FrameLength is the length of the Signal Frame, which is 420+3780 for PN420 and 945+3780 for PN945. Assignment block 1160 declares “frame sync found” by setting FS_FsFound to a one and FS_Lock to a one before proceeding to state 3 (750).

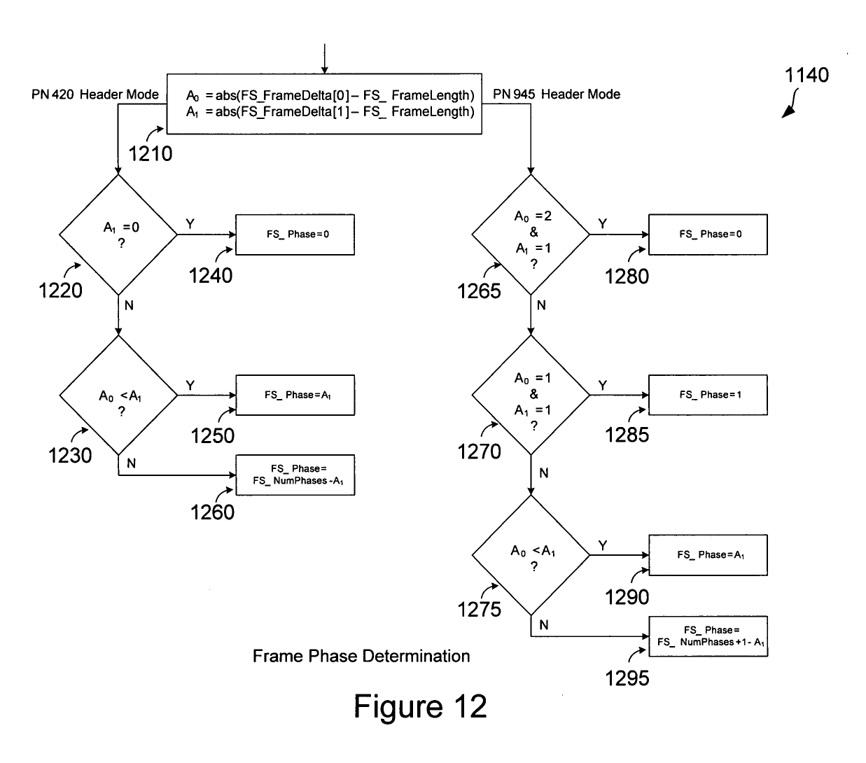

FIG. 12 shows the frame phase determination 1140 circuitry in accordance with the present invention. By performing three consecutive correlations and calculating the distance between them in FS_FrameDelta[0] and FS_FrameDelta[1], the phase of the rotating PN sequence in PN420 and PN945 can be resolved. For PN420 the frame phase can be between 0 . . . 224 (there are 225 signal frames per super frame) and for PN945, the frame phase can be between 0 . . . 199 (there are 200 signal frames per super frame). Assignment block 1210 defines two parameters based on FS_FrameDelta[0] and FS_FrameDelta[1]:

A₀=|FS_FrameDelta[0]−FS_FrameLength|

A₁=|FS_FrameDelta[1]−FS_FrameLength|

For PN420 the left side of FIG. 12 is used; decision block 1220 compares A₁ to 0. If A₁=0 then the frame phase FS_Phase is set to zero in assignment block 1240. Otherwise, decision block 1230 compares A₀ to A₁ to determine the frame phase. If A₀<A₁ then the frame phase FS_Phase is set to A₁ in assignment block 1250; otherwise, the frame phase FS_Phase is set to FS_NumMatches minus A₁ in assignment block 1260.

For PN945 the right side of FIG. 12 is used; decision block 1265 compares A₀ to 2 and A₁ to 1, and, when A₀ is equal to 2 and A₁ is equal to 1, these values, then the frame phase FS_Phase is set to 0 in assignment block 1280. Otherwise, decision block 1270 compares A₀ to 1 and A₁ to 1, and, when both A₀ and A₁ are equal to one, the frame phase FS_Phase is set to 1 in assignment block 1285. Otherwise, decision block 1275 compares A₀ to A₁, and, when A₀<A₁, the frame phase FS_Phase is set to A₁ in assignment block 1290; otherwise, the frame phase FS_Phase is set to FS_NumMatches minus A₁ plus 1 in assignment block 1295.

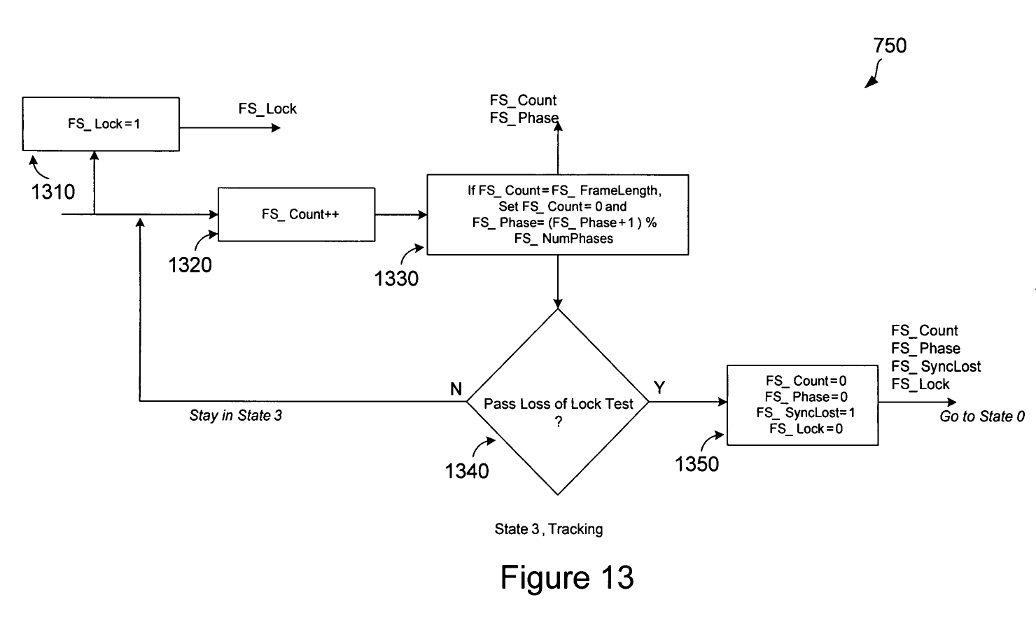

FIG. 13 shows frame synchronization state-3 in accordance with the present invention. This state is entitled “Tracking,” and monitors a loss-of-lock test 1340 to make sure the receiver stays in lock. In assignment block 1310, lock is declared when it hasn't already been declared, by setting FS_Lock to a one. The frame count FS_Count is incremented in assignment block 1320. Note that the frame count FS_Count is the symbol count within a signal frame, and therefore can range from

### PN420: 0.4199

### PN595: 0.4374

### PN945: 0.4724

In assignment block 1330, FS_Count is kept within bounds by setting FS_Count to zero when FS_Count equals the signal frame length, and FS_Phase is kept within bounds using modulo arithmetic by the number of phases (found from the number of signal frames per super frame).

Decision block 1340 checks results of a loss-of-lock test. When loss-of-lock is not declared, state 3 is re-entered; otherwise, assignment block 1350 declares a loss of lock and sets

### FS_Count= 0

### FS_Phase=0

### FS_SyncLost=1

### FS_Lock=0

before transitioning back to state 0.

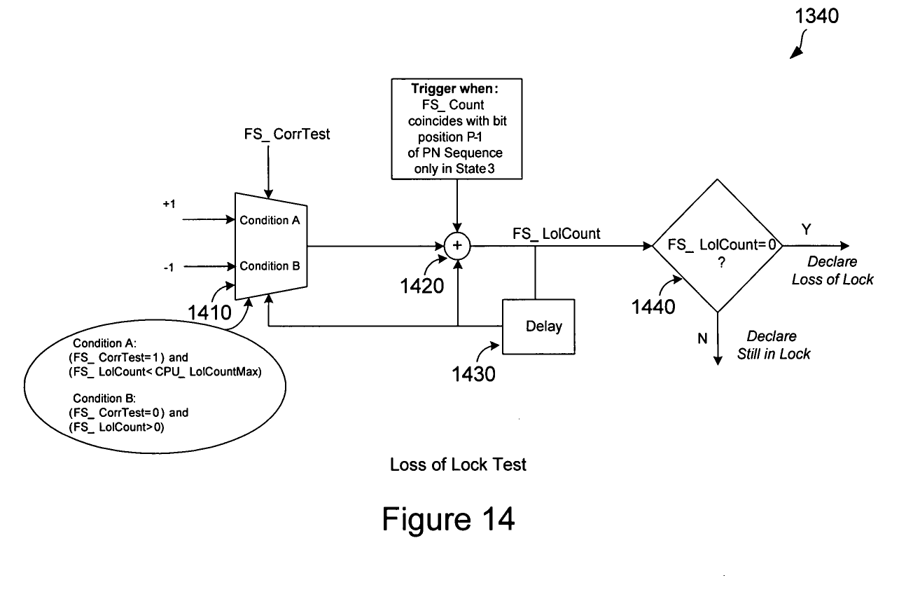

FIG. 14 shows a Frame Sync loss-of-lock test in accordance with the present invention. Lock is determined by checking the reappearance of the PN sequence every frame at the right sample index.

Note that FS_LolCount is like a bucket, or accumulator, initialized to CPU_FsLolCountMax (for example, 20). The test uses the correlation test from pre-stage correlation calculations 720 to form a decision about the state of lock. Each re-occurrence of the PN sequence, FS_LolCount is incremented or decremented, and if FS_LolCount reaches zero, then loss of lock is declared. Multiplexor 1410 provides a 1 to increment FS_LolCount when FS_CorrTest from pre-stage correlation calculations 720 is true, and FS_LolCount remains less than a programmable threshold CPU_LolCountMax (checking to make sure the bucket does not overflow). Otherwise, multiplexor 1410 provides a −1 to decrement FS_LolCount when FS_CorrTest from pre-stage correlation calculations 720 is false, and FS_LolCount>0 (checking to make sure the bucket isn't empty).

When FS_Count coincides with the P-1 position of the PN sequence in state 3, adder 1420 increments or decrements the value of FS_LolCount. Delay element 1430 stores FS_LolCount to be used on the signal next frame. Decision block 1440 checks the value of FS_LolCount, and if equal to zero, a loss-of-lock is declared; otherwise, lock is maintained.

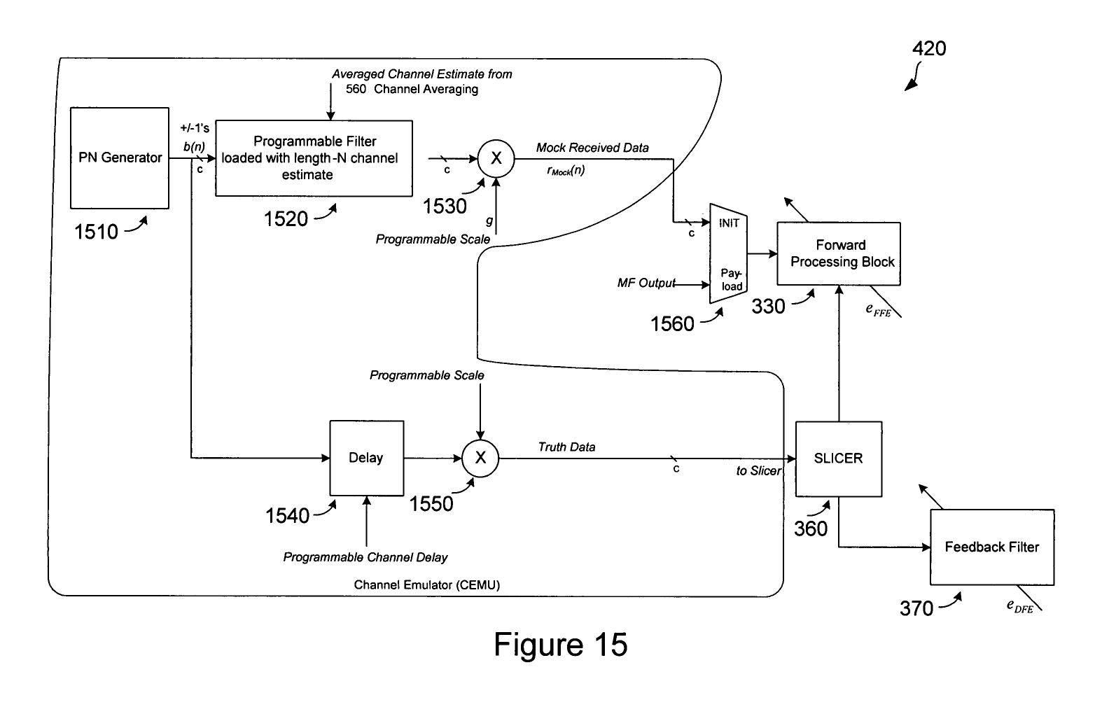

FIG. 15 shows a channel emulator in accordance with the present invention. Channel emulation block 420 creates a known data sequence, for example using a PN random number generator, and filters this known data sequence through the channel estimate provided by channel identification block 420, thus creating an input/output data record that can be used to train the adaptive filters in forward processing block 330 and feedback filter 370. Both the input and output data records are supplied from the channel emulation 420 block to forward processing block 330 to form error terms e_{FFE}(k) and e_{DFE}(k), and gain and phase correction terms β(k),e^{jθ(k)}. The output data record from the channel emulation 420 block is also supplied to slicer 360, and is used to form a feedback sample z(k), input to the feedback filter 370.

PN generator 1510 creates a real-valued or complex-values sequence of random +/−1's for example based on a PN23 implemented with a linear feedback shift register. The random data from PN generator 1510 is supplied as input to programmable filter 1520, which is loaded with filter coefficients set from the averaged channel estimate from channel averaging block 560. The filtered data output from programmable filter 1520 is scaled in multiplier 1530 by a programmable scale, which may depend on the PN header mode. The output of multiplier 1530 is used as mock received data, which during an initialization mode, before adaptation to payload data, is selected by multiplexor 1560 as input data to forward processing unit 330. It is given by

$${r}_{MOCK} ( n ) = g ( {\sum }_{k = 0}^{N -} {c}_{l} ( k ) \cdot b ( n - k ) + j \cdot {\sum }_{k = 0}^{N - 1} {c}_{Q} ( k ) \cdot b ( n - k ) )$$

where g is the programmable scale using in multiplier 1530 and b(n) is the random sequence of +/−1's from PN generator 1510. The random output of PN generator 1510 is also provided to delay element 1540, which delays the data by a value determined from a programmable channel delay. This delay will determine the position of the main equalizer coefficient, or cursor. The output of delay element 1540 is scaled by a second programmable scale in multiplier 1550, and the result is used as truth data, used to generate and equalizer error term and data for feedback filter 370 in slicer 360.

Hence, during an initialization mode, prior to processing payload data in the equalizer, (i) the mock received data generated by filtering the randomly-generated PN data through the channel estimate, and (ii) the randomly-generated PN data itself, both form input signals to the equalizer adaptive filters, one in forward processing unit 330 and other the feedback filter 370, and also are used to form an adaptive error term in forward processing unit 330 or slicer 360. The equalizer is therefore trained using the channel estimate, without ever performing a costly matrix inverse, to a setting suitable for adaptation to payload data, using channel emulation block 420.

One skilled in the art would understand that, the equations described herein may include scaling, change of sign, or similar constant modifications that are not shown for simplicity. One skilled in the art would realize that such modifications can be readily determined or derived for the particular implementation. Thus, the described equations may be subject to such modifications, and are not limited to the exact forms presented herein.

As would be apparent to one skilled in the art, the various functions of equalization, signal combining, error correction, and carrier recovery may be implemented with circuit elements or may also be implemented in the digital domain as processing steps in a software program. Such software may be employed in, for example, a digital signal processor, micro-controller, or general-purpose computer.

The present invention can be embodied in the form of methods and apparatuses for practicing those methods. The present invention can also be embodied in the form of program code embodied in tangible media, such as floppy diskettes, CD-ROMs, hard drives, or any other machine-readable storage medium, wherein, when the program code is loaded into and executed by a machine, such as a computer, the machine becomes an apparatus for practicing the invention. The present invention can also be embodied in the form of program code, for example, whether stored in a storage medium, loaded into and/or executed by a machine, or transmitted over some transmission medium, such as over electrical wiring or cabling, through fiber optics, or via electromagnetic radiation, wherein, when the program code is loaded into and executed by a machine, such as a computer, the machine becomes an apparatus for practicing the invention. When implemented on a general-purpose processor, the program code segments combine with the processor to provide a unique device that operates analogously to specific logic circuits.

It will be further understood that various changes in the details, materials, and arrangements of the parts which have been described and illustrated in order to explain the nature of this invention may be made by those skilled in the art without departing from the principle and scope of the invention as expressed in the following claims.

What is claimed is:

1. In a communications receiver having an equalizer that processes GB 20600-2006 digital television signals that include payload data, a method that initializes the equalizer coefficients for processing the payload data, the method comprising:
identifying a channel estimate based on correlation techniques;
producing known, mock received data and filtering the mock, received data through the channel estimate to produce mock filtered data;
adjusting the equalizer coefficients with the mock received data or the mock filtered data to obtain an initial equalizer setting; and
processing the payload data with the initial equalizer setting.

2. In a communications receiver having an equalizer that processes digital communications signals that include payload data, a method that initializes equalizer coefficients for processing of the payload data, the method comprising:
identifying a channel estimate based on correlation techniques;
producing known, mock received data and filtering the mock, received data through the channel estimate to produce mock filtered data;
adjusting the equalizer coefficients with the mock received data or the mock filtered data to obtain an initial equalizer setting; and
processing the payload data with the initial equalizer setting.

3. A receiver in accordance with claim 2, where at least one the equalizer coefficient is adapted over time.

4. A receiver in accordance with claim 2, where at least one the equalizer coefficient receives input from the output of the equalizer.

5. A receiver in accordance with claim 2, where at least one the equalizer coefficient receives input data prior to final frequency translation to baseband.

6. A receiver that carries out the method of claim 2, wherein the digital communications signals are GB20600-2006 digital television signals.

7. In a communications receiver that processes GB 20600-2006 digital television signals that include payload data, a method that synchronizes received data to the framing structure of the payload data, the method comprising:
correlating the received data with header information in the payload data to produce a correlation signal;
calculating a distance between peaks in the correlation signal; and
deriving position in the frame by the distance between peaks.

8. A receiver that carries out the method of claim 7, where the received data comprises of equalized output samples.

9. A receiver that carries out the method of claim 7, where the received data comprises of samples prior to equalization.

10. In a communications receive that processes GB 20600-2006 digital television signals that include payload data, a method of synchronizing the received data to the framing structure of the payload data, the method comprising:
correlating the received data with header information in the payload data to produce a correlation signal;
calculating a distance between peaks in the correlation signal;
comparing the magnitude of the peaks to prevent false lock to pre-amble or post-amble sections of the framing structure; and
deriving a position in the frame by the distance between peaks.

11. In a communications receiver that processes GB 20600-2006 digital television signals that include payload data, a method that, synchronizes received data to a framing structure of the payload data, the method comprising:
correlating the received data with stored header information in the payload data to produce a correlation signal;
calculating a distance between peaks in the correlation signal to determine a frame position; and
adjusting an index of the stored header information used in the correlation based on the frame position.

12. In a communications receiver having an equalizer that processes digital communications signals that include payload data, a method that initializes equalizer coefficients for processing of the payload data, the method comprising:
identifying a channel estimate based on correlation techniques;
deriving a channel inverse based on the channel estimate;
producing known, mock received data and filtering the mock, received data through the channel inverse producing mock filtered data;
adjusting the equalizer coefficients with the mock received data or the mock filtered data to obtain an initial equalizer setting; and
processing the payload data with the initial equalizer setting.

13. A receiver that carries out the method of claim 12, wherein the digital communications signals are GB20600-2006 digital television signals.

14. In a communications receiver having an equalizer that processes GB 20600-2006 digital television signals that include payload data, an apparatus that initializes equalizer coefficients for processing of the payload data, the apparatus comprising:
a channel estimator circuit coupled to the payload data which generates a channel estimate;
a channel emulator circuit coupled to the channel estimate which generates mock received data, and filters the mock received data through the channel estimate to create mock filtered data; and
a circuit to couple the mock received data or the mock filtered data to the equalizer coefficients for the purpose of adjusting the equalizer coefficients to produce adjusted equalizer coefficients, and using the adjusted equalizer coefficients for processing of the payload data.

15. The apparatus of claim 14, wherein at least one the adjusted equalizer coefficient is adapted over time when processing the payload data.

16. The apparatus of claim 14, wherein at least one the equalizer coefficient receives input from the output of the equalizer.

17. The apparatus of claim 14, wherein at least one the equalizer coefficient receives input data prior to final frequency translation to baseband.

18. In a communications receiver having an equalizer that processes GB 20600-2006 digital television signals that include payload data, an apparatus that synchronizes the received data to the framing structure of the payload data, the apparatus comprising:
a correlator which correlates the received data with stored or generated header information in the payload data to produce a correlation signal;
a distance calculator which measures peaks in the correlation signal and calculates a peak distance between the peaks in the correlation signal; and
a frame position circuit that derives position in the framing structure by processing the peak distance between the peaks.

19. In a communications receiver having an equalizer that processes GB 20600-2006 digital television signals that include payload data, an apparatus for synchronizing the received data to the framing structure of the payload data, the apparatus comprising:
a correlator which correlates the received data with stored or generated header information in the payload data to produce a correlation signal;
a distance calculator which measures peaks in the correlation signal and calculates a peak distance between the peaks in the correlation signal;
a comparator which measures the magnitudes of the peaks to create peak magnitudes; and
a frame position circuit that derives a position in the framing structure by processing the peak distance between the peaks and compares the peak magnitudes to prevent false lock to pre-amble or post-amble sections of the framing structure.

20. In a communications receiver having an equalizer processes GB 20600-2006 digital television signals that include payload data, an apparatus for synchronizing the received data to the framing structure of the payload data, the apparatus comprising:
a correlator which correlates the received data with stored or generated header information in the payload data to produce a correlation signal;
a distance calculator which measures peaks in the correlation signal and calculates a peak distance between the peaks in the correlation signal;
a frame position circuit that derives position in the framing structure by processing the peak distance between the peaks; and
an index adjuster which adjusts the addressing of the stored or generated header information based on the position in the framing structure.
